(19) United States
(12) Patent Application Publication
(10) Pub. No.: US 2025/0019855 A1
(43) Pub. Date: Jan. 16, 2025

(54) COATING OR SURFACE TREATMENT METHOD, SUBSTRATE AND APPARATUS

(71) Applicant: FEPOD OY LTD., Helsinki (FI)

(72) Inventor: Niklas WESTER, Helsinki (FI)

(73) Assignee: FEPOD OY LTD, Helsinki (FI)

(21) Appl. No.: 18/712,684

(22) PCT Filed: Apr. 3, 2023
(86) PCT No.: PCT/EP2023/058701

§ 371 Date: May 22, 2024

(30) Foreign Application Priority Data
Apr. 1, 2022 (FI) 20227043

(51) Int. Cl. C25D 5/02; C25D 17/00

(52) U.S. Cl. CPC C25D 5/026; C25D 17/005

(57) ABSTRACT

The present invention relates to a coating or surface treatment method. In the method, a substrate holder and slot die head are provided. The slot die head has a slit nozzle. A substrate is mounted on the substrate holder. The substrate is moved relative to the slit nozzle by supplying an electrically conductive liquid through the slit nozzle onto the substrate such that the liquid is deposited onto the substrate. A power source applies an electrical potential difference between the slit nozzle and the substrate while the conductive liquid is supplied through the slit nozzle to the substrate. The power source applies a first electrical potential to the slit nozzle and a second, different electrical potential to the substrate.

The present invention relates to a coating or surface treatment method, a coating or surface treatment apparatus, a coating or surface treatment system and a substrate coated or treated with the coating or surface treatment method. The provided method, apparatus, and system may be used for coating polymers, biopolymers, conductive polymers or metals, or electrochemically treating a conductive electrode material.

### BACKGROUND

Electrodeposition is a widely used technique capable of producing metallic and polymeric coatings using electric current on a conductive material immersed in a solution with metal ions or polymer monomers to be deposited. For example, electrochemical sensor electrodes are often coated with catalytically active metal nanoparticles, polymers, conductive polymers, and/or biopolymers. This may enhance sensitivity, improve signal-to-noise ratio, selectivity, and/or reduce electrode fouling, e.g. of sensors. In addition, electrodeposition is often applied in the production of electrodes for energy conversion and storage applications (for example supercapacitors, batteries, and fuel cells) and fabrication of flexible electronics. Sensor performance can be improved by coating electrode materials especially in the production of electrodes for electroanalysis and electrocatalysis. Example electrode materials are carbon or metal electrodes, conductive polymers, metal nanoparticles and carbon nanoparticles or a combination thereof.

In one particular example for electrodeposition, active noble metal nanoparticles such as platinum and gold may be deposited for a detection of hydrogen peroxide in enzymatic electrochemical sensors. Additionally, silver and nickel or palladium and rhodium may be deposited.

Some sensing applications require diffusion through porous layers. In these applications, a coating may advantageously have a thickness in the range of 10 to 1000 nm. A continuous thick coating (e.g., a thickness in the range of 100 nm to 10 μm) may be preferable in other applications. Electrodeposition is an efficient way of conformally coating porous electrode materials with thin functional films and metal nanoparticles.

The same process can also be used for molecular imprinting of electrodes with electrodeposited coatings, such as polydopamine and conductive polymers. With electrodeposition one can achieve conformal thin film coatings with imprinted recognition sites for a wide range of analytes. Moreover, electrodeposition techniques deposit such coatings rapidly. Conformal coating and accurate thickness control over porous conductive layers can be achieved.

Similarly, electrodeposition techniques can be applied to dissolve or break bonds using oxidative or reductive potentials as well as driving chemical reactions between molecules in the electrolyte and the electrode surface. Thus, they can be used for etching or surface chemistry modifications, such as grafting reactions. Examples for etching and surface functionalization are explained by Wei, D., Liu, Y., Cao, L., Zhang, H., Huang, L., Yu, G., Kajiura, H. and Li, Y. in “Selective Electrochemical Etching of Single-Walled Carbon Nanotubes”, Adv. Funct. Mater., 2019: 3618-3624 or by E. Leppänen, S. Sainio, H. Jiang, B. Mikladal, I. Varjos, T. Laurila, in “Effect of Electrochemical Oxidation on Physicochemical Properties of Fe-Containing Single-Walled Carbon Nanotubes”, ChemElectroChem 2020, 7, 4136. An overview over electrografting is provided by Belanger D, Pinson J. in “Electrografting: a powerful method for surface modification”, Chem Soc Rev. 2011 July; 40(7):3995-4048. Similarly, electrodeposition techniques may alter the morphology of electrode materials, for example, generating a porous surface of graphite electrodes, or greatly increasing the surface area of an electrode.

Conventionally, electrodeposition (sometimes also called electroplating) requires a bath with an electrolyte solution. An anode, made of the coating material and a cathode, which is to be coated, are immersed in the electrolyte solution. Conventionally, a solid counter electrode may also be used as the source material. In some applications, the anode may be coated. When an electrical potential is applied between the anode and the cathode, anode material may be deposited on the cathode as a layer. However, after the coating process, the bath comprising the electrolyte solution and remaining solubilized coating, e.g., cathode material must be thrown away or recycled. This is particularly disadvantageous for expensive materials such as gold, silver or platinum or for rare materials such as biomolecules and medically active substances that may be present as ionic species in the electrolyte. Thus, the electrolyte solution may need to be discarded. Moreover, in some applications, such as molecular imprinting, the template molecules may be scarce and/or prohibitively expensive.

EP 1 182 278 A2 shows a process for producing an electrodeposited copper foil. An electrolyte containing copper sulfate is charged between a cylindrical cathode drum and an anode arranged along the cathode drum with approximately a fixed gap held therebetween. Current for copper electrodeposition is supplied, so that copper is electrodeposited on the surface of the rotating cathode drum. The copper foil whose thickness has reached a given value is continuously released from the cathode drum and wound around a roll winder. However, EP 1 182 278 A2 still requires the use of an electrolyte bath, through which the substrate is fed or in which a sheet is immersed. For large sheets or wide rolls large baths are needed, this leads to waste of chemicals and generation of hazardous waste. While metal ions may be recovered from such solutions, it is more difficult to recover polymer precursor monomers, template molecules (e.g. of biological or synthetic origin) and particles from colloidal suspensions. In any case, the recovery process requires resources.

Consequently, it is an object of the present invention to provide a device and method which provides an improvement over the known processes. In particular, it is an object of the present invention to provide an electrodeposition method which leads to less waste and efficient use of the deposited materials.

### SUMMARY

This object is achieved with the features of the independent claims. Dependent claims refer to preferred embodiments.

A first aspect of the present invention relates to a coating or surface treatment method. In the method, a substrate holder and slot die head are provided. The slot die head has a slit nozzle. A substrate is mounted on the substrate holder. The substrate is moved relative to the slit nozzle by supplying an electrically conductive liquid through the slit nozzle onto the substrate such that the liquid is deposited onto the substrate. A power source applies an electrical potential difference between the slit nozzle and the substrate while the conductive liquid is supplied through the slit nozzle to the substrate. The power source applies a first electrical potential to the slit nozzle and a second, different electrical potential to the substrate.

Contrary to the known processes, the proposed electrodeposition does not require a bath. Rather, a slot die coating process is modified and used in electrodeposition. In the proposed method, the substrate is coated with the precise amount that is required. There is only a minimal amount of waste of deposited materials. When the coating or treatment has ended, any remaining electrically conductive liquid can be stored and used at another point in time without requiring a recovery of materials from a bath. Further, the invention can enable faster through-put times for surface treatment and coating.

A coating or surface treatment method may refer to any one of the following: electrophoretic deposition of charged particles, electrodeposition, electrochemical treatment, etching, and electrochemically driven grafting reactions. In general, any conductive material can be coated with functional materials or be functionalized to tailor the substrate for many applications. An electrodeposition according to the invention can be carried out with a reductive or oxidative reaction at the substrate. Functionalization may also refer to oxidation or reduction of the electrode surface to alter surface chemistry (e.g., removal of oxides from metals or adding oxygen containing functional groups to carbon electrodes).

Grafting reactions may occur at the substrate surface to enable surface functionalization with for example amines and carboxylic acids. For example, aliphatic amines can be covalently bound to carbon and metal electrodes by initiating radical formation electrochemically. These radicals are generated preferentially at the electrode surface and attach to the surface though subsequent chemical reactions and or electrochemical reactions. Grafting reactions may functionalize conductive materials to allow for improved sensor performance, electrocatalysis, catalysis and or immobilization of molecules and biorecognition elements.

The electrically conductive liquid may comprise dissolved ions, molecules or particles that are dissolved or suspended. The electrically conductive liquid may be a conductive electrolyte with metal salts/ions or monomer precursors for electropolymerization. The used electrolyte may depend on the material to be deposited and the substrate. In one example, the electrolyte may be a salt electrolyte such as KCl or lithium perchlorate. These electrolytes may be useful for polymers. Optionally highly conductive electrolytes may be used to reduce the resistivity of the electrically conductive liquid. The conductivity of the electrically conductive liquid may vary from 0.5 to 1000 S/m. Optionally, less conductive electrolytes such as acetonitrile or low ionic strength liquids can be used.

In a preferred embodiment, the electrical potential difference of the power source is adjustable, and the method comprises the step of adjusting the electrical potential between the slit nozzle and the substrate. In a preferred embodiment the power source comprises an adjustable current source and the method comprises the step of adjusting the electrical current between the slit nozzle and the substrate. Thus, the method can be adapted for different processes. Further, the potential difference may be reduced (and optionally increased again) while the substrate is moved further relative to the slot die head such that only portions of the substrate are coated or treated.

In a preferred embodiment, the conductive liquid contacts the substrate electrode and slit nozzle such that a closed-circuit is formed.

In a preferred embodiment, an electrode is deposited on the substrate subsequent, prior to, or by (i.e., while) moving the substrate relative to the slit. In one example, the method provided above may be used for depositing an electrode on a substrate. In a further example, the electrode deposited using the above process may be further coated or treated using the above process again. In some embodiments, the electrode may be patterned. Alternatively, electrodes can be deposited prior to the above process by first depositing a conductive layer and then patterning the conductive layer. The conductive layer may be deposited by screen printing, dip coating, slot die coating, spray coating, physical vapor deposition, chemical vapor deposition, and/or dry transfer a conductive material. A pattern may be generated by subsequently patterning for example by standard lithography. In other examples, the pattern may be applied using laser patterning. Optionally, conductive patterns may be directly deposited by screen printing conductive inks, physical vapor deposition through a shadow mask, stencil printing and inkjet printing or a combination thereof. Alternatively, patterns to be coated can be defined by patterned dielectric layers that can be deposited onto conductive substrates by depositing and patterning or directly depositing patterned dielectric layers as above. Alternatively or additionally, polymer layers with adhesives may be patterned with stencil printing, laser patterning and applied as dielectric layers onto conductive substrates. Then, these electrodes may be further coated and/or treated with the methods described above and below.

In another example, the electrode may include an array of electrodes. The array may comprise electrodes in the size ranges of 0.1 μm to 200 μm for electrophysiology or electrochemical measurements of single cells and electrodes.

In some embodiments, the substrate may comprise a first electrode, that may be patterned as described above, and a second electrode. The first electrode may be treated or coated as described herein. The second electrode may form a reference electrode that can be used to monitor the electrical potential in the electrically conductive liquid. The first and second electrode and the slit nozzle may be connected to a potentiostat. This allows for more accurate control of the potential and/or current at the first electrode (working electrode).

In a preferred embodiment the deposition step comprises depositing a conductive pattern that forms the electrode.

In a preferred embodiment the method additionally or alternatively comprises the step of pretreating the electrode electrochemically. Alternatively, the method outlined above may also be used to treat the substrate and an electrode arranged thereon. In one example the treatment may include oxidizing or passivating electroactive metal particles and/or surface functional groups whose oxidation may cause background current in an electrode. This may include oxidizing or reducing plasticizers and other contaminants in the electrode.

The oxidization may be caused by applying the electrical potential difference. This may preclude the need to use aggressive organic solvents or acids and can be applied for disposable electrodes and flexible electronics on polymer substrates. For example, active electrode materials are susceptible to fouling with organic molecules of atmospheric origin or that are present as contaminants in polymer substrates (for example bisphenol A and phthalates). These surface contaminants can affect both sensor performance and subsequent processing steps, where clean gold (linking with thiol chemistry) or carbon surfaces are required (7L-7L stacking). Such contaminants may be removed with the proposed method and apparatus. Similarly metallic contaminants, for example Fe catalysts used to grow carbon nanotubes, can be oxidized, whereby they become ionic species that are soluble in aqueous solutions. Also, this may be used when electrode materials such as carbon nanotubes are deposited on polymers and need to be removed from the polymers. The carbon nanotubes can be effectively stripped from the surface by oxidizing them electrochemically.

In one example the proposed method and apparatus can also be used to pattern carbon nanotube films. For example, a part of the substrate may be protected, for example, with non-reactive, e.g. photo-resistive, layer. The layer may be subsequently removed. In addition, the proposed process could be used for selective etching of metallic single walled carbon nanotubes leaving behind only semiconducting nanotubes. The general process chemistry is explained by Wei, D., Liu, Y., Cao, L., Zhang, H., Huang, L., Yu, G., Kajiura, H. and Li, Y. in “Selective Electrochemical Etching of Single-Walled Carbon Nanotubes”, Adv. Funct. Mater., 2019: 3618-3624.

Another example of the inventive method is functionalizing the surface of a carbon electrode with oxygen containing functional groups that can alter the affinity of various molecules to the surface and thus improve selectivity and sensitivity of sensors. With aqueous or mild acids as electrically conductive liquid, the carbon electrode can be oxidized so that the carbon electrode becomes decorated with oxygen containing functional groups. By controlling the electrically conductive liquid composition and applied potential difference, formation of certain functional groups can be favored. For example, carboxylic groups are highly desirable as they can be activated with EDC/NHS.

In a preferred embodiment, the slot die head and the substrate are positioned relative to each other such that the conductive liquid forms a meniscus between the slit nozzle and the substrate when supplied from the slit nozzle. The meniscus may complete an electrical circuit between the slit nozzle and the substrate. The meniscus may help in spreading the electrically conductive liquid over the substrate evenly. A portion of the slot die head directed towards the substrate may have a triangular shape. In one particular example, the slot die head may have a flat end face (e.g. a blunt slit nozzle) or the slot die head may be pointed (i.e. a sharp slit nozzle). A blunt slit nozzle may reduce the current density at the slit nozzle and thus reduce risk of gas evolution (e.g. hydrogen evolution when depositing conductive polymers).

In a preferred embodiment the potential difference is 0.1 V or more and/or 50 V or less. In other embodiments, the potential difference may be at least 0.2, 0.3, 0.5, 0.7, 1, 2, 5, 10 or 15 V. In further embodiments, the potential difference may be at most 0.3, 0.5, 0.7, 1, 2, 5, 7, 10, 15, 20, 25 or 30 V. In some applications, the electrical potential applied to the slit nozzle is higher than the electrical potential applied to the substrate (denoted herein as positive voltages). In other applications the electrical potential applied to the substrate may be higher than the electrical potential to the slit nozzle (denoted herein as negative voltages). Any of the voltages mentioned above may denote a positive or a negative voltage. The power source may supply a direct or alternative current.

The substrate may be rigid or flexible. In a preferred embodiment, the method is sheet based or a roll-to-roll process. In a sheet-based process, the substrate may be a sheet, for example a rigid, planar sheet, and the sheet is transported below the slit nozzle (or vice versa). In a roll-to-roll process, a flexible substrate is rolled from one roll to another. The flexible substrate may be coated or treated in between rolls or while on a roll.

The invention may, for example be, implemented using conventional slot die coaters and the respective slot die heads and providing them with external connections as will be described below. One example slot die head is manufactured by FOM TECHNOLOGIES (e.g. “Research series| XX-Large”).

In a preferred embodiment, the method additionally comprises the step of heating the substrate before, during and/or after supplying the conductive liquid. For example, the holding device may include a heater, e.g., one or more heated rolls, for heating the substrate. The apparatus may comprise means for generating a negative pressure or vacuum. This allows for combining heat and/or vacuum treatments with the coating or surface treatment.

In a preferred embodiment the electrically conductive liquid comprises metal particles, optionally nickel (Ni), platinum (Pt), gold (Au), iron (Fe) cadmium (Ca), chromium (Cr), copper (Cu), titanium (Ti), zinc (Zn), brass and/or silver (Ag). These particles are particularly suited for coating electrodes and sensors. The metal particles may be present in a colloidal suspension, e.g., as microparticles or nanoparticles, in the electrically conductive liquid. If metal particles are present in a colloidal suspension, they may be deposited electrophoretically.

In another embodiment, the particles may be soluble as ionic species in the electrically conductive liquid. In this case they may be electrodeposited through, e.g., electrochemical reduction. These materials may be used in electrocatalytic applications, such as energy conversion and storage as well as in sensor applications. The deposition of noble metals may be used in a thiol-based immobilization of molecules such as antibodies, aptamers and enzymes.

In a preferred embodiment, the electrically conductive liquid comprises electrically conductive polymers, optionally PANI, polypyrrole, PEDOT, and/or PEDOT:PSS. The electrically conductive polymers may be deposited electrophoretically as polymer particles in suspension or from precursor monomers in the suspension (for example aniline, pyrrole, EDOT, EDOT PSS mixture). In the latter, a polymerization reaction may be initiated at the substrate surface by oxidizing the monomers into radical species that lead to polymerization. These substances may be useful for spectroelectrochemical applications, such as electrochemiluminescence. In one embodiment, one or more conductive polymer and/or non-conductive polymer layers may be electrodeposited onto one or more electrodes.

Optionally said materials or material combination may be optically transparent. Optically transparent material combinations include, but are not limited to, polypyrrole, PEDOT, PEDOT:PSS or any other doped conductive polymer, graphene, single-walled carbon nanotubes, multi-walled carbon nanotubes, amorphous carbon and a combination thereof.

The thickness of the layer may be controlled through the amount of liquid supplied through the slit nozzle and the relative movement speed between the slit nozzle and the substrate. Further, the thickness of the layer may be controlled through the potential difference. The conductive polymers may be deposited in a layer having a thickness of about 2 nm to about 1000 nm. Such thin layers may function as a binder and protective layers for nanomaterial electrodes that also provide an additional electrochemically active area, and surface functionalization.

The conductive polymers may also be deposited in a layer having a thickness of about 100 nm to about 10 μm. This may provide for conductors and/or mechanical protection. Deposited conductive polymer layers may also function as highly porous layers in antifouling films in complex matrices for milk, other foods, and biological samples such as blood. Further, a conductive polymer layer may functionalize electrode materials such as metal foils or non-conductive substrates with conductive seed layers to provide inexpensive electrodes with improved electrochemical properties.

While the method may be used to coat the substrate as described above, the present method can also be used to treat electrodes on a substrate. In a preferred embodiment the electrically conductive liquid comprises a chemical etching agent. Example chemical etching agents are hydrochloric acid (HCl), sulfuric acid (H₂SO₄), nitric acid (HNO₃), and/or any mixture thereof. In the context of etching, the electrically conductive liquid may comprise sodium chloride (NaCl), potassium chloride (KCl). The electrodes may comprise carbon or metal, such as carbon nanotubes, and/or single-walled carbon nanotubes graphene. These electrodes may be electrochemically etched. After the treatment or irrespective of the treatment, the carbon electrodes may be functionalized with conductive polymers (e.g., transparent conductive polymers) using the same method (with a different liquid and potential difference) to reduce biofouling, increase surface area, or improve a conductivity. In some embodiments, the electrochemical etching may be combined with a conventionally known chemical etching. This may have the example that it is possible to add more energy (at room temp) to drive chemical reactions at the surface electrochemically than with purely chemical means. For example, simple aqueous electrolytes with salt (or milder) acids may be used for oxidation of carbon instead of using concentrated heated acids baths with long reaction times.

In the context of etching, the electrolyte could also be only a salt solution (eg NaCl or KCl). It is advantageous if reaction product of the contamination species (after electrochemical reaction) is soluble or dispersible in the electrolyte and thus can be washed away from the surface.

In a preferred embodiment, the substrate comprises optically transparent electrodes.

In a preferred embodiment, the electrically conductive liquid comprises a template molecule. The template molecules may be deposited in the layer, e.g., polymer layer. The method may further comprise the step of washing out the template molecule after the electrically conductive liquid has been deposited. For example, molecular imprinting or entrapping and washing away the template molecules to generate surfaces capable of specifically recognizing the template in sensing applications may be used. Such surfaces are also referred to as synthetic receptors.

Adding template molecules allows for electrodeposition of molecularly imprinted polymer layers that contain sites for recognizing the template molecules. The polymer layer may be electrically conductive. For example, methanol, acetone, ethanol, isopropanol, acids, bases, oxidative or reductive electrochemical treatments may be used as solvents for washing out the template molecule. The washout may also use the method described above, but with a different electrically conductive liquid, i.e., one of the previously mentioned solvents. This leaves behind empty sites capable of selectively binding the template molecule. One particular example for this involves selective measurements of paracetamol in blood samples.

In some embodiments, the method may additionally apply an inert gas blanket during, before, and/or after supplying the electrically conductive liquid. This may minimize oxidation of reactive reagents, such as oxygen sensitive precursor chemicals. In some embodiments, the apparatus comprises a glove box or other airtight vessel for applying the inert atmosphere. The inert atmosphere may comprise or (substantially) consist of, for example, nitrogen or argon.

In one embodiment of the method, the method comprises a step of co-depositing microparticles or nanoparticles, molecules, biomolecules, proteins with a conductive or non-conductive matrix or any combination thereof. Conductive or non-conductive particles may be embedded in a conductive or non-conductive matrix. The microparticles or nanoparticles may be made of metals, conductive or nonconductive polymers. The microparticles or nanoparticles may be functionalized. In one embodiment, platinum or gold nanoparticles may be suspended in a EDOT or pyrrole containing electrolyte, enabling co-deposition of metal particles and conductive polymer in one step. In electroanalysis and electrocatalysis conductive catalytically active particles can be embedded in an optionally conductive, optionally non-conductive, matrix. Iron and iron oxide metal nanoparticles may be co-deposited with conductive polymers to improve electrocatalytic properties or serve as redox mediators that chemically react with, for example, enzyme cofactors in biosensors.

A further aspect is directed to a substrate coated with the coating method described above. The coating method described above may lead to a more even distribution of the coated material. Unlike conventional electrodeposition the present invention allows for a patterning of substrate to be coated. This could be achieved by increasing or decreasing the potential difference as the substrate is moved relative to the slot die head. The potential difference may also be switched on and off. In contrast, such patterning would require using a patterned insulator layer in conventional electrodepositions. The present method can also be combined a masking using a dielectric layer. A patterning provided by increasing decreasing the potential difference as the substrate is moved will have a unique characteristic as compared to a conventional patterning.

In a further aspect of the present invention, a coating or surface treatment apparatus is provided. The apparatus comprises a substrate holder for holding a substrate. The apparatus comprises a slot die head comprising a slit nozzle. The slit nozzle and the substrate are configured to move relative to each other. The slot die head is configured to supply a conductive liquid through the slit nozzle onto the substrate. The apparatus also comprises a power source that is configured to provide a potential difference. The power source is electrically connected to the slit nozzle and includes an interface for an electrical connection to the substrate. The power source is configured to provide the potential difference between the slit nozzle and the substrate.

The slot die head may comprise an inlet for the coating. The slot die head may comprise a fluid reservoir for holding the electrically conductive liquid in the slot die head. The apparatus may comprise a pump and/or a dosing device for the electrically conductive liquid. The pump may be configured to feed the electrically conductive liquid into the slot die head. The substrate holder may comprise support rollers for holding and/or moving the substrate. In another example, the substrate holder comprises sample holders (e.g., to hold individual substrate samples). In a further example, the substrate holder may comprise a vacuum holder to hold the sample substrate to be coated in place during the coating process.

The slit nozzle is electrically conductive to form an electrode. The slot die head may be made of or include a conductive material, e.g., a conductive metal. For example, the slot die head could be made of a metal such as aluminum, titanium, brass, or steel. Thereby, the power source can be connected to any part of the slot die head without necessarily needing to be directly connected to the slit nozzle.

In one example, the surface of the slot die head (excluding the slit nozzle) is coated with a dielectric material or anodized to reduce electrical interference and risk for users.

The slot die head may be separable into two parts. A shim may be inserted between the parts to adjust the width of the slit nozzle. The slit nozzle may have a length of 150 to 300 mm. The slit nozzle may have a linear nozzle opening, optionally a straight linear nozzle opening. In some embodiments, the apparatus may comprise a liquid reservoir outside of the slot die head. The liquid reservoir may be fluidly connected to the liquid reservoir outside of the slot die head. The apparatus may further comprise a filter and/or a degasification device for the electrically conductive liquid.

In a preferred embodiment, the electrical potential difference of the power source is adjustable. Thereby, the slit nozzle can be adjusted to the production process, in particular to depositing different materials, different material combinations, depositing at different speeds, etc. Further, adjusting the electrical potential or switching the potential on and off may allow for selectively depositing or treating certain areas of the substrate.

In a preferred embodiment, the power source comprises an adjustable current source. In some processes it may be preferable to adjust the electrical potential difference by setting a fixed current rather than by setting a fixed electrical potential difference, i.e., voltage. The power source may comprise an ampere meter to monitor the current that is passing through the system. Thereby, the electrochemical reactions can be monitored.

A coating can be deposited on the substrate for example through reduction of metal ions or oxidation of monomers to form polymer coatings. In addition, electrophoretic deposition of charged particles can be carried out by biasing the substrate. The kinetics of these reactions and thus the resulting morphology, particle size and thickness can be controlled with the applied potential, or by controlling the current that flows through the system. Similarly, the morphology, particle size and thickness of the coating can be controlled by changing the composition of the supporting electrolyte (for example ionic strength, pH, choice of ions, choice of precursor, and precursor concentration).

A further aspect of the invention is directed to a system comprising the apparatus described above and a substrate. The substrate may comprise polymers, ceramics, metals or any combination thereof. The substrate is electrically connected to the power source.

In a preferred embodiment the substrate includes, or forms an electrode connected to the interface of the power source. In some embodiments, the substrate may comprise a layer that is electrically connected to the power source. In other embodiments, only certain parts of the substrate may be electrically conductive to form a counter electrode with respect to the slit nozzle. For example, the substrate may include a pattern that forms the electrode. In this case material may only be deposited on the parts forming the electrode.

### BRIEF DESCRIPTION OF THE DRAWINGS

The subject matter of the invention will be explained in more detail in the following text with reference to preferred exemplary and non-limiting embodiments which are illustrated in the attached schematic drawings. These figures disclose embodiments of the invention for illustrational purposes only. In particular, the disclosure provided by the figures and description is not meant to limit the scope of protection conferred by the invention.

FIG. 1 depicts a schematic drawing of an apparatus according to the invention.

FIG. 2 depicts a schematic top view of a portion of the apparatus according to FIG. 1 and a substrate with a first and second electrode in detail.

FIG. 3 shows an image of an apparatus according to the invention.

FIG. 4 shows an image of an inner part of a slot they had according to the invention.

FIGS. 5A and 5B show a round SWCNT film on polymer substrate partially coated with polypyrrole layer.

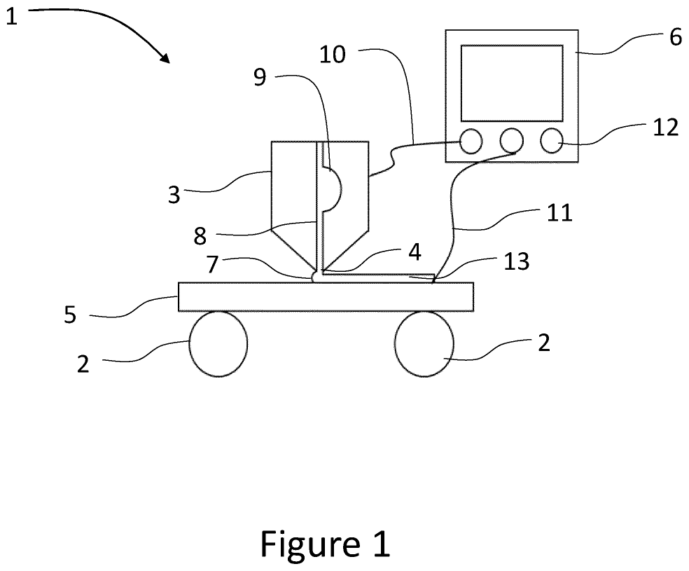

FIG. 1 depicts a coating or surface treatment apparatus 1 schematically. The apparatus comprises a slot die head 3 with a slit 8. The apparatus also comprises a fluid reservoir and a pump (not shown) for supplying an electrically conductive liquid into the slit 8. The slit 8 may include, within the slot die head 3, a slot die head reservoir 9. A pump may be configured to maintain the electrically conductive liquid under pressure, such that the electrically conductive liquid is evenly expelled through a slit nozzle 4.

The apparatus 1 also comprises a substrate holder. Here, the substrate holder is formed by support rollers 2. A substrate 5 may be held on the support rollers 2 and be transported with the support rollers below the slot die head 3. As an alternative, the slot die head 3 may be moved over the substrate 5 which is held in place. Further, the apparatus comprises a power source 6. The power source 6 is electrically connected to the slot die head with a wire 10. The slot die head 3 is made of an electrically conductive material such as stainless steel. Further, power source 6 is connected to the substrate 5 by a wire 11. The power source 6 is adapted to provide a potential difference between the slot die head 3 and the substrate 5, i.e., a voltage is applied between the slot die head 3 and the substrate 5. The power source 6 may also be connected to a reference electrode with a wire using interface 12. The power source 6 comprises or may be connected to a potentiostat to control the potential of the substrate to be coated 5 in a multiple electrode electrochemical cell.

When electrically conductive liquid is expelled from the slit nozzle 4, the expelled electrically conductive liquid forms a meniscus 7 and while moving the substrate 5 under the slot die head, a layer 13 of electrically conductive liquid is deposited onto the substrate as usual in slot die coating methods. While the electrically conductive liquid is deposited onto the substrate, the power source applies a potential difference between the slit nozzle 4 and the substrate 5. This electrical potential in combination with the electrically conductive liquid is used to coat or treat the substrate as described herein.

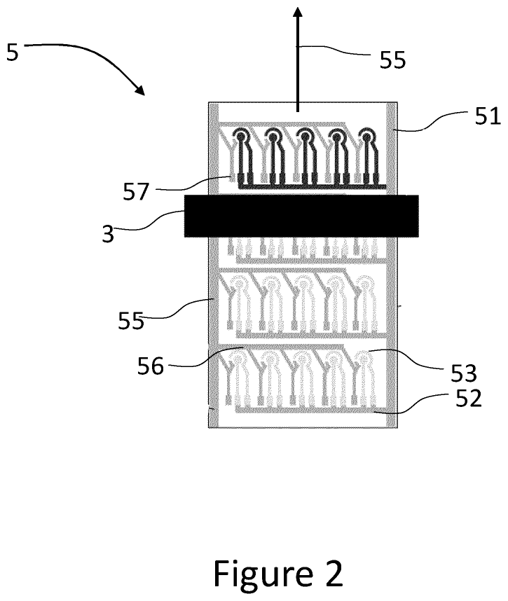

In a particular application, a polymer sheet with a single-walled carbon nanotube (SWCNT) film was used as substrate 5 to be treated. The electrically conductive liquid is 37% hydrochloric acid diluted 200 times with deionized water. The substrate 5 includes a frame around the edges of the SWCNT film to contact the wire 11 and the power source 6. Optionally, Ag wires could be printed across the area to be treated to sense the potential of the treated electrode to compensate for the ohmic losses in the system as will be explained with reference to FIG. 2. The Ag wires could also be covered with a dielectric material to reduce gas evolution on the substrate and allow for more precise potential sensing since only an area that is close to the electrode to be coated is exposed to the potential.

A positive (oxidative) potential is applied to the substrate 5 and negative (reductive) to the slot die head 3. The highly hydrophobic SWCNT surface allows the electrolyte to be dragged along the surface without leaving traces of electrolyte and thus further reduces chemical consumption.

The potential can be increased to 35 V until current visual etching of the SWCNT is observed. Alternatively, the current passing through the system could be controlled and limited. In this way a large potential can be selected, and the system can apply the required potential to achieve the desired current flowing through the system. This provides positive feedback for compensating the resistance across the electrically conductive liquid to some extent. The removal of SWCNT takes place in less than 1 min. Thus, an efficient removal of SWCNT in desired regions may be affected.

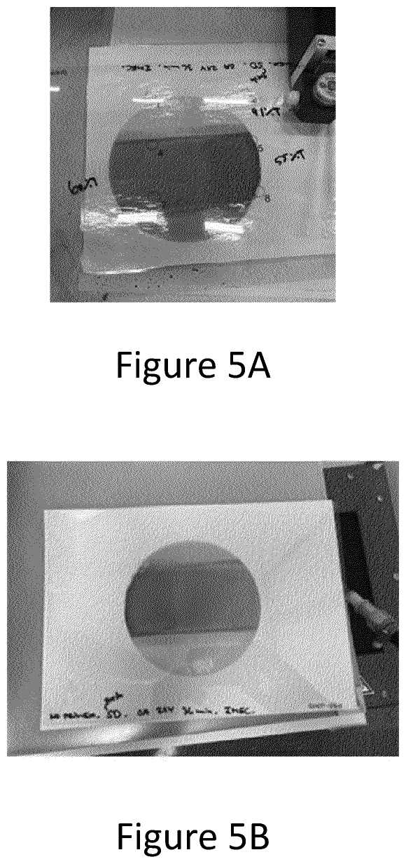

In another particular application, a polymer sheet with a SWCNT film was used as substrate 5. Here, the wire 11 was directly attached to the SWCNT film. The electrically conductive liquid is a pyrrole monomer solution in 1 M KCl. A potential difference of 10 V was applied across the slit nozzle 4 and the substrate 5. The positive potential was applied to the SWCNT film. Thereby, a polypyrrole coating is applied. The resulting coating can be seen in FIGS. 5A and 5B.

In a further example, a non-cured Nafion layer is treated. These layers may contain impurities from processing that cause increased background current and unstable backgrounds. In one embodiment, such impurities can be oxidized by applying potential differences in the range of −0.2V to 3V and using phosphate buffered saline or other simple aqueous solutions with salts, e.g. KCl, as electrolytes. Mild acids could also be used (e.g., 0.1 M sulfuric acid) as the electrolyte. Due to the oxidation, contaminants are removed and/or or active surface functionalities are passivated, and the background current of the electrochemical sensors is stabilized.

Further use cases of the apparatus 1 are described above.

FIG. 2 shows a top view of a portion of the slot die head 3 and the substrate 5 and illustrates an example electrode configuration. The substrate 5 is moved in the direction of arrow 55 below the slot die head 3. The substrate 5 comprises a first electrode and a second electrode. The first electrode (also working electrode) is connected to the power source 6 comprising a potentiostat and used to apply the potential difference. The first electrode comprises a contacting strip 51, a connection strip 52, and an end portion 53. The first electrode is a laser patterned CNT electrode. The end portion 53 is intended to be coated with a conductive polymer to enhance sensor performance as described above. In another example, electropolymerization molecular imprinting as described above is used to functionalize the end portion 53. Further, the second electrode also comprises a contacting strip 55, a connection strip 56, and an end portion 57. The first and second electrode may be screen-printed using Ag as is conventionally known. The second electrode (also reference electrode) is used to measure the currently applied potential difference to monitor and adjust the potential difference precisely. Then, using the apparatus 1 and slot die head 3, carbon nanotubes may be deposited onto the first electrode. The contacting strips 51 and 55 are electrically connected to the wires and the power source 6. Alternatively, electrical contact can be achieved by conductive metal rolls that are pressed against the contacting strips 51 and 55. In this way continuous roll-to-roll electrodeposition or electrochemical treatments may be carried out. The second electrode is a screen-printed and made of Ag.

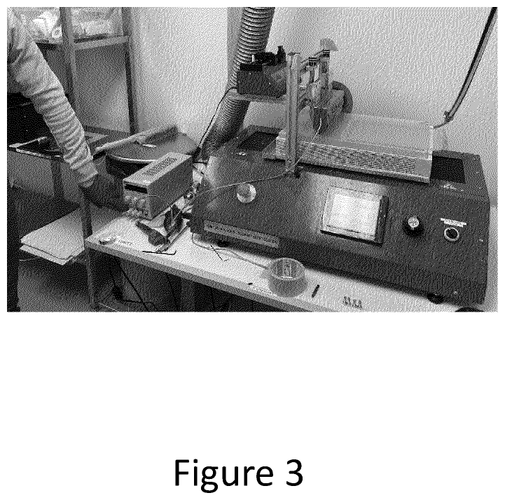

FIG. 3 shows an image of coating or surface treatment apparatus 1. The apparatus comprises a substrate holder (conveyor belt with a red casing) and a slot die head mounted on top of the substrate holder. A substrate is held on a conveyor belt and transported with respect to the slot die head. The slot die head is connected via a wire to the power source (gray box).

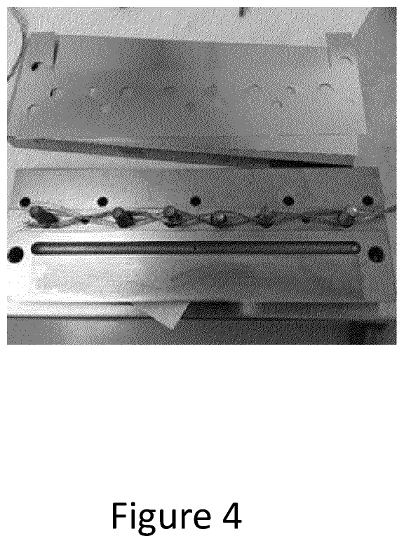

As explained above, the slot die head may be separated into two parts. The slot ahead 3 as shown in FIG. 1 may, for example be separable along slit 8 as shown in FIG. 1. FIG. 4 shows one half of the slot die head. In the particular example, the slot die head halfs are connected with screws (or otherwise) and the wire connecting the slot die head and the power source is intermeshed with the screws connecting the halfs of the slot die head. In a particularly simple embodiment, the bear strands of the wire may be wound around the individual screws connecting the halfs of the slot the heads as shown in FIG. 4. FIG. 4 also shows a shim that may be inserted between the parts to adjust the width of the slit nozzle (perforated sheet metal).

While the invention has been illustrated and described in detail in the drawings and foregoing description, such illustration and description are to be considered illustrative or exemplary and non-restrictive; the invention is thus not limited to the disclosed embodiments. Variations to the disclosed embodiments can be understood and effected by those skilled in the art and practicing the claimed invention, from a study of the drawings, the disclosure, and the appended claims. In the claims, the word “comprising” does not exclude other elements or steps, and the indefinite article “a” or “an” does not exclude a plurality and may mean “at least one”.

The following are preferred aspects of the invention:

1. A coating or surface treatment method comprising the following steps:
providing a substrate holder (2) and a slot die head (3), the slot die head having a slit nozzle (4);
   mounting a substrate (5) on the substrate holder;
moving the substrate relative to the slit nozzle while supplying an electrically conductive liquid through the slit nozzle onto the substrate such that the liquid is deposited onto the substrate; and
applying an electrical potential difference between the slit nozzle and the substrate using a power source (6) while supplying the conductive liquid through the slit nozzle to the substrate, wherein the power source applies a first potential to the slit nozzle and a second different electrical potential to the substrate.

2. Method according to aspect 1, wherein the electrical potential difference of the power source is adjustable, the method comprising the step of:
adjusting the electrical potential between the slit nozzle and the substrate.

3. Method according to aspect 1 or 2, wherein the power source comprises an adjustable current source comprising the step of:
adjusting the electrical current between the slit nozzle and the substrate.

4. Method according to one of the preceding aspects, wherein the conductive liquid contacts the substrate and slit nozzle such that a closed circuit is formed.

5. Method according to one of the previous aspects, comprising the following step:
depositing an electrode on the substrate prior to or by moving the substrate relative to the slit nozzle.

6. Method according to aspect 5, wherein the depositing step comprises depositing a conductive pattern that forms the electrode.

7. Method according to one of aspects 3 to 6, additionally comprising the step of pre-treating the electrode electrochemically.

8. Method according to one of the previous aspects, comprising the following step:
positioning the slot die head and the substrate relative to each other such that the conductive liquid forms a meniscus (7) between the slit nozzle and the substrate when supplied from the slit nozzle.

9. Method according to one of the previous aspects, wherein the potential difference is 0.1V or more and/or 50V or less.

10. Method according to one of the previous aspects, wherein the method is a sheet based or a roll-to-roll process.

11. Method according to one of the previous aspects, comprising the following step:
heating the substrate before, during and/or after supplying the conductive liquid.

12. Method according to one of the previous aspects, wherein the electrically conductive liquid comprises metal particles, preferably Ni, Pt, Au, Fe and/or Ag.

13. Method according to one of the previous aspects, wherein the electrically conductive liquid comprises electrically conductive polymers, optionally PANI, polypyrrole, PEDOT, and/or PEDOT:PSS.

14. Method according to one of the previous aspects, wherein the substrate comprises optically transparent electrode materials, optionally carbon nanotubes, single-walled carbon nanotubes, graphene, and/or indium tin oxide.

15. Method according to one of the previous aspects, wherein the electrically conductive liquid comprises a chemical etching agent, optionally hydrochloric acid, sulfuric acid or nitric acid or mixtures thereof.

16. Method according to one of the previous aspects, wherein the electrically conductive liquid comprises a template molecule, and wherein the method further comprises the step of washing out the template molecule after the electrically conductive liquid has been deposited.

17. A substrate (4) coated with the coating method according to one of the previous aspects.

18. A coating or surface treatment apparatus (1) comprising,
a substrate holder (2) for holding a substrate;
a slot die head (3) comprising a slit nozzle (4), wherein the slit nozzle and the substrate are configured to move relative to each other; the slot die head being configured to supply a conductive liquid through the slit nozzle onto the substrate;
a power source (6) configured to provide an electrical potential difference, wherein the power source is electrically connected to the slit nozzle and includes an interface for an electrical connection to the substrate, and wherein the power source is configured to provide the electrical potential difference between the slit nozzle and the substrate.

19. Apparatus according to aspect 18, wherein the slit nozzle is made of an electrically conductive material.

20. Apparatus according to one of aspects 18 or 19, wherein the electrical potential difference of the power source is adjustable.

21. Apparatus according to one of aspects 18 to 20, wherein the power source comprises an adjustable current source.

22. System comprising an apparatus according to one of aspects 18 to 21 and a substrate.

23. System according to aspect 22, wherein the substrate includes or forms an electrode (21) connected to the interface of the power source.

24. System according to aspect 22 or 23, wherein the substrate comprises an electrode (21) and wherein the electrode is patterned.

24. System according to aspect 22 or 23, wherein the substrate comprises a second electrode, wherein the second electrode is reference electrode for measuring an electrical potential.

1.-25. (canceled)

26. A coating or surface treatment method comprising the following steps:
providing a substrate holder and a slot die head, the slot die head having a slit nozzle;
mounting a substrate on the substrate holder;
moving the substrate relative to the slit nozzle while supplying a conductive liquid through the slit nozzle onto the substrate such that the conductive liquid is deposited onto the substrate; and
applying an electrical potential difference between the slit nozzle and the substrate using a power source while supplying the conductive liquid through the slit nozzle to the substrate, wherein the power source applies a first potential to the slit nozzle and a second different electrical potential to the substrate.

27. The method according to claim 26, wherein the electrical potential difference of the power source is adjustable, the method comprising the step of:
adjusting the electrical potential between the slit nozzle and the substrate.

28. The method according to claim 26, wherein the power source comprises an adjustable current source comprising the step of:
adjusting the electrical current between the slit nozzle and the substrate.

29. The method according to claim 26, wherein the conductive liquid contacts the substrate and slit nozzle such that a closed circuit is formed.

30. The method according to claim 26, comprising the following step:
depositing an electrode on the substrate prior to or by moving the substrate relative to the slit nozzle.

31. The method according to claim 30, wherein the depositing step comprises depositing a conductive pattern that forms the electrode.

32. The method according to claim 30, additionally comprising the step of pre-treating the electrode electrochemically.

33. The method according to claim 26, comprising the following step:
positioning the slot die head and the substrate relative to each other such that the conductive liquid forms a meniscus between the slit nozzle and the substrate when supplied from the slit nozzle.

34. The method according to claim 26, wherein the potential difference is between 0.1V-50V.

35. The method according to claim 26, wherein the method is a sheet based or a roll-to-roll process.

36. The method according to claim 26, comprising the following step:
heating the substrate before, during and/or after supplying the conductive liquid.

37. The method according to claim 26, wherein the electrically conductive liquid comprises metal particles.

38. The method of claim 37, wherein the electrically conductive liquid comprises metal particles of Ni, Pt, Au, Fe or Ag.

39. The method according to claim 26, wherein the electrically conductive liquid comprises electrically conductive polymers.

40. The method of claim 39, wherein the electrically conductive liquid comprises PANI, polypyrrole, PEDOT, or PEDOT:PSS.

41. The method according to claim 26, wherein the substrate comprises an optically transparent electrode material.

42. The method of claim 41, wherein the optically transparent electrode material is one or more of carbon nanotubes, single-walled carbon nanotubes, graphene, or indium tin oxide.

43. The method according to claim 26, wherein the electrically conductive liquid comprises a chemical etching agent.

44. The method of claim 43, wherein the chemical etching agent is hydrochloric acid, sulfuric acid, nitric acid, or mixtures thereof.

45. The method according to claim 26, wherein the electrically conductive liquid comprises a template molecule, and wherein the method further comprises the step of washing out the template molecule after the electrically conductive liquid has been deposited.

46. A substrate coated with the coating method according to claim 26.

47. A coating or surface treatment apparatus comprising,
a substrate holder for holding a substrate;
a slot die head comprising a slit nozzle, wherein the slit nozzle and the substrate are configured to move relative to each other; the slot die head being configured to supply a conductive liquid through the slit nozzle onto the substrate; and
a power source configured to provide an electrical potential difference, wherein the power source is electrically connected to the slit nozzle and includes an interface for an electrical connection to the substrate, and wherein the power source is configured to provide the electrical potential difference between the slit nozzle and the substrate.

48. The apparatus according to claim 47, wherein the slit nozzle is made of an electrically conductive material.

49. The apparatus according to claim 47, wherein the electrical potential difference of the power source is adjustable.

50. The apparatus according to claim 47, wherein the power source comprises an adjustable current source.

51. A system comprising an apparatus according to claim 47 and a substrate.

52. The system according to claim 51, wherein the substrate includes or forms an electrode connected to the interface of the power source.

53. The system according to claim 51, wherein the substrate comprises an electrode and wherein the electrode is patterned.

54. The system according to claim 51, wherein the substrate comprises a second electrode, wherein the second electrode is reference electrode for measuring an electrical potential.
